(19) United States
(12) Patent Application Publication
(10) Pub. No.: US 2022/0165995 A1
(43) Pub. Date: May 26, 2022

(54) SELECTIVE FILLER PATTERNING BY LITHOGRAPHY FOR OLED LIGHT EXTRACTION

(71) Applicant: Applied Materials, Inc., Santa Clara, CA (US)

(72) Inventors: Chung-Chia CHEN, New Taipei City (TW); Byung-sung Leo KWAK, Portland, OR (US); Robert Jan VISSER, Menlo Park, CA (US)

(21) Appl. No.: 17/104,188

(22) Filed: Nov. 25, 2020

(51) Int. Cl. H01L 51/56; H01L 27/32; H01L 51/52

(52) U.S. Cl. CPC H01L 51/56; H01L 51/5253; H01L 27/3246

(57) ABSTRACT

Embodiments of the present disclosure generally relate to electroluminescent (EL) devices. More specifically, embodiments described herein relate to methods for forming arrays of the EL devices and selectively patterning a filler material in the EL devices. The EL device formed from the methods described herein will have improved outcoupling efficiency because of the patterned filler. The methods described herein pattern the filler and provide large area, low cost, and high resolution EL device formation by not relying on ink-jet printing or thermal evaporation with a fine metal mask.

### BACKGROUND

### Field

Embodiments of the present disclosure generally relate to electroluminescent (EL) devices. More specifically, embodiments described herein relate to methods for forming arrays of the EL devices and selectively patterning a filler material in the EL devices.

### Description of the Related Art

Organic light-emitting diode (OLED) technologies have become an important next-generation display technology offering many advantages (e.g., high efficiency, wide viewing angles, fast response, and potentially low cost). In addition, as a result of improved efficiency, OLEDs are also becoming practical for some lighting applications. Even so, typical OLEDs still exhibit significant efficiency loss between internal quantum efficiency (IQE) and external quantum efficiency (EQE).

Through certain combinations of electrode materials, carrier-transport layers, e.g., hole-transport layers (HTLs) and electron-transport layers (ETLs), emission layers (EMLs), and layer stacking, IQE levels can reach nearly 100%. However, EQE levels of typical OLED structures remain limited by optical outcoupling inefficiencies. Outcoupling efficiencies can suffer from optical energy loss due to significant emitting light being trapped by total internal reflection (TIR) inside the OLED display pixels.

Typical top-emitting OLED structures include a substrate, a reflective electrode over the substrate, organic layer(s) over the reflective electrode, and a transparent or semi-transparent top electrode over the organic layer(s). Due to higher refractive indices of the organic layer(s) and top electrode relative to air, significant emitting light is confined by TIR at the device-air interface preventing outcoupling to air. A filler material having a high refractive index (i.e., about greater than 1.8) can be selectively patterned to fill the OLED display pixels. However, typical filler patterning processes such as large area ink-jet printing or thermal evaporation through a fine metal mask (FMM) are not ideal for high resolution applications.

Accordingly, what is needed in the art are improved methods for forming arrays of the EL devices and selectively patterning a filler material in the EL devices.

### SUMMARY

In one embodiment, a method is provided. The method includes disposing a protection layer over a top electrode layer of an electroluminescent (EL) device. The method further includes disposing a filler on the protection layer. The method further includes disposing a photoresist on the filler. The photoresist is disposed over a planar region, sidewall regions, and PDL regions of the EL device. The planar region and the sidewall regions correspond to an area of the EL device to have the filler disposed thereover. The method further includes patterning the photoresist. The patterning of the photoresist includes removing portions of the photoresist corresponding to the PDL regions of the EL device. The method further includes etching exposed portions of the filler corresponding to the PDL regions of the EL device. The filler remains over the planar region and the sidewall regions of the EL device. The method further includes removing the photoresist.

In another embodiment, a method is provided. The method includes disposing a protection layer over a top electrode layer of an electroluminescent (EL) device. The method further includes disposing a photoresist on the protection layer. The photoresist is disposed over a planar region, sidewall regions, and PDL regions of the EL device. The planar region and the sidewall regions correspond to an area of the EL device to have a filler disposed thereover. The method further includes patterning the photoresist. The patterning of the photoresist includes removing portions of the photoresist corresponding to the planar region and the sidewall regions of the EL device. The method further includes disposing the filler on the photoresist and exposing the filler and remaining photoresist. The method further includes removing the photoresist.

In yet another embodiment, a method is provided. The method includes disposing a protection layer over a top electrode layer of an electroluminescent (EL) device. The method further includes disposing a photoresist on the protection layer. The photoresist is disposed over a planar region, sidewall regions, and PDL regions of the EL device. The planar region and the sidewall regions correspond to an area of the EL device to have a filler disposed thereover. The method further includes patterning the photoresist. The patterning of the photoresist includes removing portions of the photoresist corresponding to the planar region and the sidewall regions of the EL device. The method further includes disposing the filler on exposed portions of the protection layer corresponding to the planar region and the sidewall regions of the EL device and on the photoresist. The method further includes removing the photoresist and the filler corresponding to the PDL regions of the EL device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, top view of an array of electroluminescent (EL) devices, according to embodiments described herein.

FIG. 1B is a schematic, side view of the array of EL devices of FIG. 1A, according to embodiments described herein.

FIGS. 1C and 1D are schematic, side sectional view of an individual EL device taken along section line 1-1 of FIG. 1A, according to embodiments described herein.

FIGS. 2A-2C are schematic views of a processing system, according to embodiments described herein.

FIG. 3 is a flow diagram of a method for forming an EL device, according to embodiments described herein.

FIGS. 4A-4H are cross-sectional views of a substrate during a method of forming the EL device, according to embodiments described herein.

FIG. 5 is a flow diagram of a method for forming an EL device, according to embodiments described herein.

FIGS. 6A-6H are cross-sectional views of a substrate during a method of forming the EL device, according to embodiments described herein.

FIG. 7 is a flow diagram of a method for forming an EL device, according to embodiments described herein.

FIGS. 8A-8G are cross-sectional views of a substrate during a method of forming the EL device, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to electroluminescent (EL) devices. More specifically, embodiments described herein relate to methods for forming arrays of the EL devices and selectively patterning a filler material in the EL devices. The EL device formed from the methods described herein will have improved outcoupling efficiency because of the patterned filler. In one embodiment, a method is provided. The method includes disposing a protection layer over a top electrode layer of an electroluminescent (EL) device. The method further includes disposing a filler on the protection layer. The method further includes disposing a photoresist on the filler. The photoresist disposed over a planar region, sidewall regions, and PDL regions of the EL device. The planar region and the sidewall regions correspond to an area of the EL device to have the filler disposed thereover. The method further includes patterning the photoresist. The patterning of the photoresist includes removing portions of the photoresist corresponding to the PDL regions of the EL device. The method further includes etching exposed portions of the filler corresponding to the PDL regions of the EL device. The filler remains over the planar region and the sidewall regions of the EL device. The method further includes removing the photoresist.

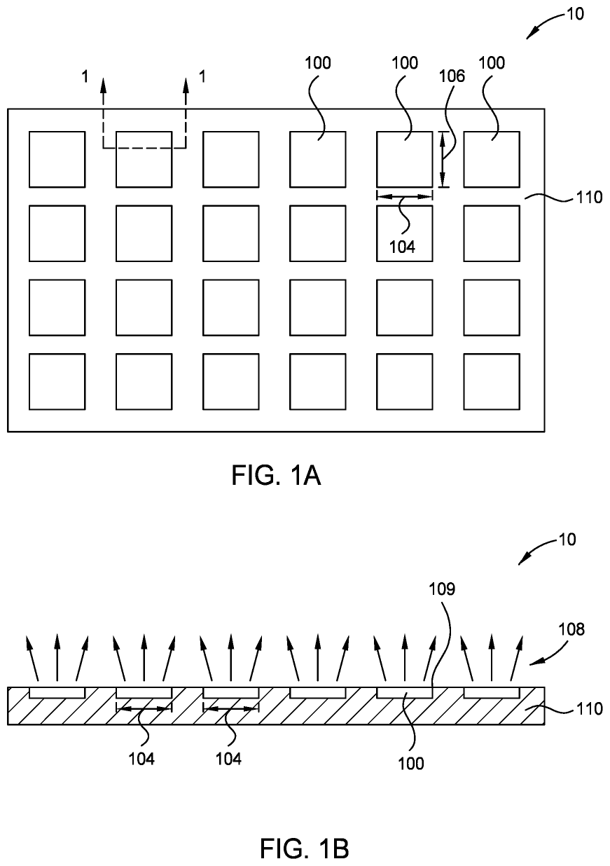

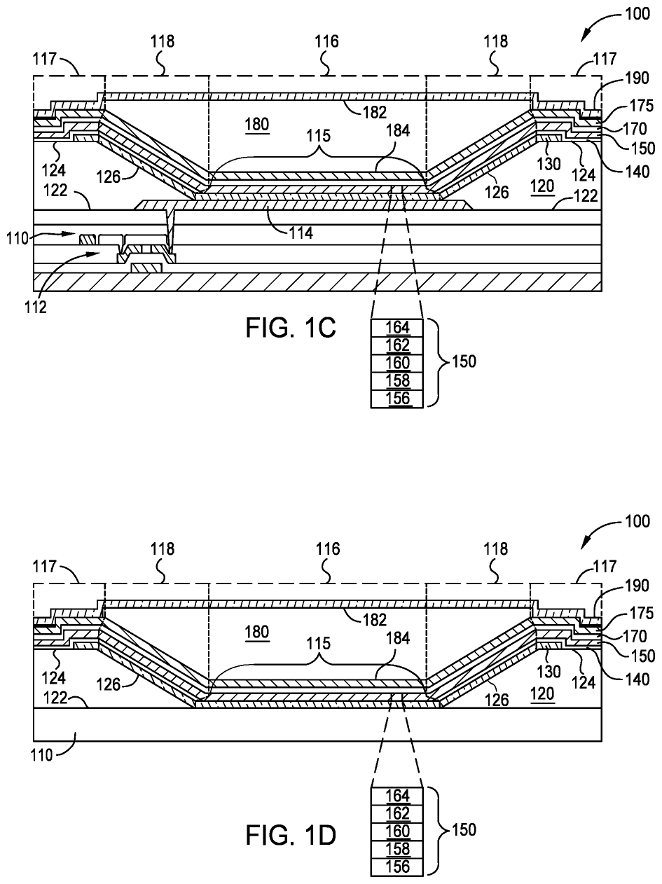

FIG. 1A is a schematic, top view of an array 10 of electroluminescent (EL) devices 100, according to embodiments described herein. The EL devices 100 and the array 10 may be fabricated by the methods 300, 500, and 700 described herein. The array 10 is formed on a substrate 110. In certain embodiments, the EL devices 100 may be OLED display pixels, and the array 10 may be a top-emitting active matrix OLED display (top-emitting AMOLED) structure. In some examples, a width 104 and a length 106 of the EL devices 100 may be from about 1 μm or less up to about 200 μm.

FIG. 1B is a schematic, side view of the array 10 of EL devices 100 of FIG. 1A, according to embodiments described herein. Here, the EL devices 100 (shown in phantom) are top-emitting and outcoupled light 108 exits the EL devices 100 from a top 109 thereof.

FIGS. 1C and 1D are schematic, side sectional views of an individual EL device 100 taken along section line 1-1 of FIG. 1A, according to embodiments described herein. The EL device 100 generally includes a pixel definition layer (PDL) 120, a bottom reflective electrode layer 130, a dielectric layer 140, and an organic layer 150. The EL device 100 further includes one or more of a top electrode layer 170, a protection layer 175, a filler 180, or an encapsulation layer 190 disposed over the organic layer 150 in a multi-layer stack. The EL device 100 includes a planar region 116 that corresponds to an area of the EL device 100 where the bottom reflective electrode layer 130, the organic layer 150, the top electrode layer 170, and the protection layer 175 are parallel with the substrate 110 between adjacent PDLs 120. The EL device 100 further includes sidewall regions 118 that correspond to an area of the EL device 100 where the bottom reflective electrode layer 130, the dielectric layer 140, the organic layer 150, the top electrode layer 170, and the protection layer 175 are disposed on PDL sidewalls 126 of the PDL 120. The EL device 100 further includes PDL regions 117 that correspond to an area of the EL device 100 where the bottom reflective electrode layer 130, the dielectric layer 140, the organic layer 150, the top electrode layer 170, the protection layer 175, and the encapsulation layer 190 are disposed on a top surface 124 of the PDL 120.

As shown in FIG. 1C, a thin-film transistor (TFT) 112 is formed on the substrate 110. The array 10 of EL devices 100 may be an OLED pixel array for a display. An interconnection layer 114 is in electrical contact between the TFT 112 and the bottom reflective electrode layer 130. The EL device 100 electrically contacts the interconnection layer 114 via the bottom reflective electrode layer 130. In some embodiments, the EL device 100 includes a planarization layer (not shown) formed over the substrate 110. As shown in FIG. 1D, the bottom reflective electrode layer 130 is in contact with the substrate 110. In some embodiments, the substrate 110 may be formed from one or more of a silicon, glass, quartz, plastic, or metal foil material. In one embodiment, which can be combined with other embodiments described herein, a metal layer (not shown) is patterned on the substrate 110. The metal layer is pre-patterned on the substrate 110. The metal layer is configured to operate as an anode for each EL device 100. The metal layer may include, but is not limited to, chromium, titanium, gold, silver, copper, aluminum, indium tin oxide (ITO) or other suitably conductive materials. In one embodiment, which can be combined with other embodiments described herein, the metal layer is a multi-layer structure. For example, a multi-layer structure including an ITO, silver, ITO layer stack.

The PDL 120 is disposed over the substrate 110. The PDL 120 may be a photoresist formed from any suitable photosensitive organic or polymer-containing material. In one embodiment, which can be combined with other embodiment described herein, a bottom surface 122 of the PDL 120 contacts the substrate 110, the interconnection layer 114, or both. The top surface 124 of the PDL 120 is facing away from the substrate 110. An emission region 115 is defined as the area where the bottom reflective electrode layer 130 is in direct contact with the organic layer 150. The dielectric layer 140 will prevent conduction between the organic layer 150 and the bottom reflective electrode layer 130 and thus the organic layer 150 will not emit light. The layers corresponding to the emission region 115 such as the organic layer 150 and the bottom reflective electrode layer 130 have refractive indices higher than that of air.

As shown in FIGS. 1C and 1D, the bottom reflective electrode layer 130 is in the planar region 116 disposed between adjacent PDLs 120. The bottom reflective electrode layer 130 in the planar region 116 is patterned between the PDLs 120 and is operable to be a bottom electrode. In one embodiment, which can be combined with other embodiments described herein, the bottom reflective electrode layer 130 in the planar region 116 is an anode. Additionally, the bottom reflective electrode layer 130 is in the sidewall regions 118 and the PDL regions 117 and disposed over the PDL 120. The bottom reflective electrode layer 130 in the sidewall regions 118 and the PDL regions 117 is patterned to be on the PDL sidewalls 126 and a portion of the top surface 124 of the PDL 120 and is operable to be a reflective layer. In one embodiment, which can be combined with other embodiments described herein, the bottom reflective electrode layer 130 in the planar region 116 and the bottom reflective electrode layer 130 in the sidewall regions 118 and PDL regions 117 are different layers. For example, the bottom reflective electrode layer 130 in the sidewall regions 118 and the PDL regions 117 may be made of a non-metal material. The bottom reflective electrode layer 130 in the planar region 116 may be a different material than the PDL regions 117 and the sidewall regions 118. In another embodiment, which can be combined with other embodiments described herein, the bottom reflective electrode layer 130 in the planar region 116 and the bottom reflective electrode layer 130 in the sidewall regions 118 and PDL regions 117 are not physically connected.

In one embodiment, which can be combined with embodiments described herein, the bottom reflective electrode layer 130 may be a blanket layer and conformal to the interconnection layer 114 and the PDL sidewalls 126. In another embodiment, which can be combined with other embodiments described herein, the bottom reflective electrode layer 130 may be a monolayer. In yet another embodiment, which can be combined with other embodiments described herein, the bottom reflective electrode layer 130 may be a multi-layer stack.

The dielectric layer 140 is disposed over the bottom reflective electrode layer 130. The dielectric layer 140 is a blanket layer disposed in the PDL region 117 and the sidewall region 118. In one embodiment, which can be combined with other embodiments described herein, the dielectric layer 140 may overlap the opposed lateral ends of the bottom reflective electrode layer 130 in the planar region 116 without extending over the entire planar region 116. The dielectric layer 140 may include any suitable low-k and high transparency dielectric material or any organic or polymer-containing material.

The organic layer 150 includes a plurality of organic sublayers such as a hole injection layer (HIL) 156, a hole transport layer (HTL) 158, an emissive layer (EML) 160, an electron transport layer (ETL) 162, and an electron injection layer (EIL) 164. The organic layer 150 is not particularly limited to the illustrated embodiment. For example, in another embodiment, which can be combined with other embodiments described herein, one or more organic sublayers may be omitted from the organic layer 150. In yet another embodiment, one or more additional organic sublayers may be added to the organic layer 150. In yet another embodiment, which can be combined with other embodiments described herein, the organic layer 150 may be inverted such that the plurality of organic sublayers are reversed. In one embodiment, which can be combined with other embodiments described herein, layers of the plurality of organic sublayers are patterned while other sublayers of the plurality of organic layers are deposited as blanket layers. For example, the EML 160 is patterned on the EL device 100 using a fine metal mask (FMM). The EML 160 will be deposited only in the planar region 116. The EIL 164, ETL 162, HIL 156, and HTL 158 are blanket layers deposited using an open mask and will therefore be deposited in the planar region 116, the PDL region 117, and the sidewall region 118.

The top electrode layer 170 is disposed over the organic layer 150. In one embodiment, which can be combined with other embodiments described herein, the top electrode layer 170 is a cathode. In another embodiment, which can be combined with other embodiments described herein, the top electrode layer 170 is a blanket layer deposited with an open mask. The top electrode 170 may be conformal to the organic layer 150. The protection layer 175 is disposed over the top electrode layer 170. The protection layer 175 protects the underlying layers from subsequent processes that may be performed on the EL device 100. In one embodiment, which can be combined with other embodiments described herein, the protection layer 175 is a blanket layer. The protection layer 175 includes, but is not limited to, one of more of silicon oxide (SiO₂), silicon nitride (SiNx), silicon oxynitride (SiON), silicon carbon oxynitride (SiCON), silicon carbonnitride (SiCN), aluminum oxide (Al₂O₃), titanium oxide (TiO₂), tantalum oxide (Ta₂O₅), hafnium oxide (HfO₂), zirconium oxide (ZrO₂), or another dielectric material.

The filler 180 is disposed over the protection layer 175. As illustrated in FIGS. 1C and 1D, the filler 180 is patterned such that the filler 180 is disposed in the planar region 116 and the sidewall region 118. The filler 180 includes an upper surface 182 and a lower surface 184. The lower surface 184 of the filler 180 is in contact with the protection layer. In one embodiment, which can be combined with other embodiments described herein, the filler 180 is patterned so that the upper surface 182 of the filler 180 is disposed above the protection layer 175. An advantage of the patterned filler 180 is improved external optical outcoupling efficiency from the EL device 100. This may be due, at least in part, to reduced lateral waveguide light leakage in the reduced thickness of the patterned filler 180.

In one embodiment, which can be combined with other embodiments described herein, the filler 180 may include one or more high refractive index materials such as a refractive index of 1.8 or greater or index-matching materials. In one or more embodiments, which can be combined with other embodiments described herein, the filler 180 may be highly transparent. The filler 180 includes, but is not limited to, one or more of organic materials, inorganic materials, polymers, resins, or combinations thereof. The one or more inorganic materials include, but are not limited to, one or more of metal oxides, metal nitrides, colloidal mixtures, or combinations thereof. Examples of the one or more metal oxides include, but are not limited to Al₂O₃, TiO, TaO, or combinations thereof. Examples of the one or more metal nitrides include, but are not limited to aluminum nitride (AlN), SiN, SiON, TiN, TaN, or combinations thereof. Examples of the colloidal mixtures include, but are not limited to TiO₂, zirconium oxide (ZrO₂), or combinations thereof. The one or more organic materials include, but are not limited to N′-Bis(napthalen-1-yl)-N, N′-bis(phenyl)benzidine, n-prophybromide, or combinations thereof. The filler 180 has a filler refractive index equal to or higher than the refractive indices of the layers corresponding to the emission region 115.

The encapsulation layer 190 is disposed over the EL device 100. In one embodiment, which can be combined with other embodiments described herein, the encapsulation layer 190 is a blanket layer and is therefore conformal to the filler 180 and the protective layer 175. In another embodiment, which can be combined with other embodiments described herein, the encapsulation layer 190 is patterned. The encapsulation layer 190 protects the EL device 100 from moisture and oxygen ingress. In one embodiment, which can be combined with other embodiments described herein, the encapsulation layer 190 can be a multi-layer stack. For example, the encapsulation layer 190 is formed from alternating layers of polymer materials and dielectric materials. The dielectric material includes, but is not limited to an inorganic material such as silicon nitride (SiNx), silicon oxide (SiOx), silicon oxynitride (SiON), or aluminum oxide (Al₂O₃).

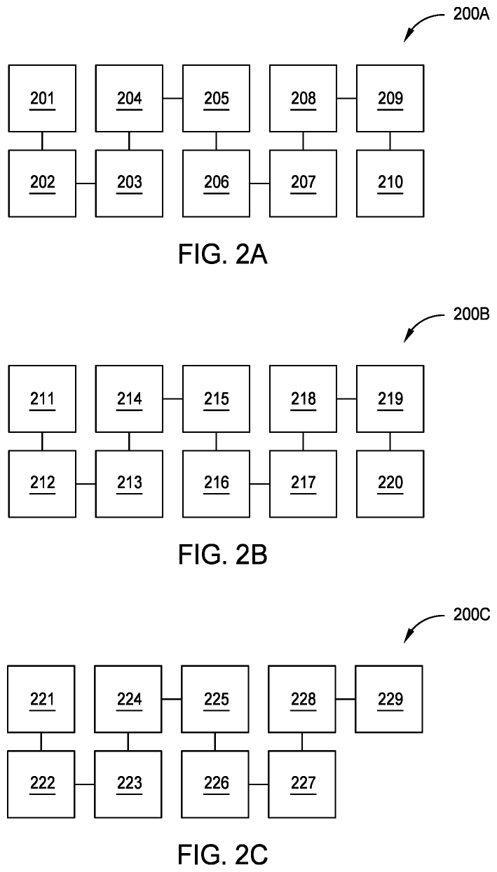

FIG. 2A is a schematic view of a processing system 200A as described herein. The process system 200A is a multi-chamber system that can form the EL device 100. The processing system 200A is utilized in the method 300, as described herein. The process system 200A includes one or more chambers 201. The one or more chambers 201 are configured to deposit an organic layer 150 and top electrode layer 170. The organic layer 150 can further include a hole injection layer (HIL) 156, a hole transport layer (HTL) 158, an emissive layer (EML) 160, an electron transport layer (ETL) 162, and an electron injection layer (EIL) 164. The hole injection layer (HIL) 156, the hole transport layer (HTL) 158, the emissive layer (EML) 160, the electron transport layer (ETL) 162, the electron injection layer (EIL) 164, and the top electrode layer 170 can be deposited in the one or more chambers 201. The one or more chambers 201 include but are not limited to chambers configured for thermal evaporation under vacuum, ink jet printing (IJP), sputtering, or any other suitable technique, or combinations thereof.

The process system 200A further includes a chamber 202. The chamber 202 is configured to deposit a protection layer 175. The chamber 202 includes, but is not limited to, a chamber configured for chemical vapor deposition (CVD), physical vapor deposition (PVD), atomic layer deposition (ALD), sputtering, plasma-enhanced chemical vapor deposition (PECVD) or any other suitable technique, or combinations thereof. In one embodiment, which can be combined with other embodiments described herein, the protection layer 175 is deposited in the chamber 202 utilizing a CVD process. The process system 200A further includes a chamber 203. The chamber 203 is configured to deposit a filler 180. The chamber 203 includes, but is not limited to, a chamber configured for PVD, CVD, PECVD, FCVD, ALD, sputtering, thermal evaporation, ink jet printing (IJP), dip coating, spray coating, blade coating, vapor jet printing, and spin-on coating or any other suitable technique, or combinations thereof. In one embodiment, which can be combined with other embodiments described herein, the filler 180 is disposed in the chamber 203 utilizing an IJP process. The process system 200A further includes a chamber 204. The chamber 204 is configured to deposit a photoresist 402. The chamber 204 includes, but is not limited to, a chamber configured for slit coating, spin coating, blade coating, spray coating, ink jet printing, or combinations thereof.

The process system 200A further includes a chamber 205. The chamber 205 is configured to expose the photoresist 402 to electromagnetic radiation. The chamber 205 includes, but is not limited to, a chamber configured to have a stepper, scanner, or combinations thereof. In one embodiment, which can be combined with other embodiments described herein, a pre-exposure bake is performed on the photoresist 402 prior to entering the chamber 205. In another embodiment, which can be combined with other embodiments described herein, a post-exposure bake is performed on the photoresist 402 after entering the chamber 205.

The process system 200A further includes a chamber 206. The chamber 206 is configured to develop the photoresist 402. The chamber 206 includes, but is not limited to, a chamber configured to have a bath, dipping bath, ultrasonic bath, spray chamber or combinations thereof.

The process system 200A further includes a chamber 207. The chamber 207 is configured to etch the filler 180. The chamber 207 includes, but is not limited to, a chamber configured for ion-beam etching, reactive ion etching, electron beam etching, wet etching, dry etching, or combinations thereof. The process system 200A further includes a chamber 208. The chamber 208 is configured to remove the photoresist 402. The chamber 208 includes, but is not limited to, chambers configured to have a bath, dipping bath, ultrasonic bath, spray chamber or combinations thereof. The process system 200A further includes one or more chambers 209. The one or more chambers 209 are configured to dry and/or cure the filler 180. The one or more chambers include but are not limited to chambers configured for vacuum drying, UV exposure, thermal drying, thermal curing, or combinations thereof. The processing system 200A further includes one or more chambers 210. The chambers 210 are configured to deposit an encapsulation layer 190. The chambers 210 include but are not limited to a chamber configured for IJP, CVD, ALD, sputtering, or combinations thereof. The encapsulation layer 190 can be a multi-layer stack. In one embodiment, which can be combined with other embodiments described herein, one encapsulation layer 190 of the one or more encapsulation layers 190 is deposited in one of the chambers 210 utilizing an IJP process. A subsequent encapsulation layer 190 of the one or more encapsulation layers 190 is deposited in one of the chambers 210 utilizing a CVD process.

FIG. 2B is a schematic view of a processing system 200B as described herein. The process system 200B is a multi-chamber system that can form the EL device 100. The processing system 200B is utilized in the method 500, as described herein. The process system 200B includes one or more chambers 211. The one or more chambers 211 are configured to deposit an organic layer 150 and the top electrode layer 170. The organic layer 150 can further include a hole injection layer (HIL) 156, a hole transport layer (HTL) 158, an emissive layer (EML) 160, an electron transport layer (ETL) 162, and an electron injection layer (EIL) 164. The hole injection layer (HIL) 156, the hole transport layer (HTL) 158, the emissive layer (EML) 160, the electron transport layer (ETL) 162, the electron injection layer (EIL) 164, and the top electrode layer 170 can be deposited in the one or more chambers 211. The one or more chambers 211 include but are not limited to chambers configured for thermal evaporation under vacuum, ink jet printing, sputtering, or any other suitable technique, or combinations thereof.

The process system 200B further includes a chamber 212. The chamber 212 is configured to deposit a protection layer 175. The chamber 212 includes, but is not limited to, a chamber configured for CVD, PVD, ALD, sputtering, PECVD, or any other suitable technique, or combinations thereof. In one embodiment, which can be combined with other embodiments described herein, the protection layer 175 is deposited in the chamber 212 utilizing a CVD process.

The process system 200B further includes a chamber 213. The chamber 213 is configured to deposit a photoresist 602. The chamber 213 includes, but is not limited to, a chamber configured for slit coating, spin coating, blade coating, spray coating, ink jet printing or combinations thereof.

The process system 200B further includes a chamber 214. The chamber 214 is configured to expose the photoresist 602 to electromagnetic radiation. The chamber 214 includes, but is not limited to, a chamber configured to have a stepper, scanner or combinations thereof. In one embodiment, which can be combined with other embodiments described herein, a pre-exposure bake is performed on the photoresist 602 prior to entering the chamber 214. In another embodiment, which can be combined with other embodiments described herein, a post-exposure bake is performed on the photoresist 602 after entering the chamber 214.

The process system 200B further includes a chamber 215. The chamber 215 is configured to develop the photoresist 602. The chamber 215 includes, but is not limited to, a chamber configured to have a bath, dipping bath, ultrasonic bath, spray chamber or combinations thereof.

The process system 200B further includes a chamber 216. The chamber 216 is configured to deposit a filler 180. The chamber 216 includes, but is not limited to, a chamber configured for PVD, CVD, PECVD, FCVD, ALD, sputtering, thermal evaporation, ink jet printing (IJP), dip coating, spray coating, blade coating, vapor jet printing, and spin-on coating or any other suitable technique, or combinations thereof. In one embodiment, which can be combined with other embodiments described herein, the filler 180 is disposed in the chamber 216 utilizing an IJP process. The process system 200B further includes a chamber 217. The chamber 217 is configured to cure the filler 180 and de-polymerize the remaining photoresist. The chamber 217 includes, but is not limited to, a chamber configured for UV radiation, thermal curing or combinations thereof. The processing system 200B further includes a chamber 218. The chamber 218 is configured to remove the photoresist 602 and the filler 180 in the PDL region 117. The chamber 218 includes, but is not limited to, a chamber configured to have a bath, dipping bath, ultrasonic bath, spray chamber or combinations thereof.

The process system 200B further includes one or more chambers 219. The one or more chambers 219 are configured to dry and/or cure the filler 180. The one or more chambers 219 include but are not limited to chambers configured for vacuum drying, UV exposure, thermal drying, thermal curing or combinations thereof. The processing system 200B further includes one or more chambers 220. The chambers 220 are configured to deposit an encapsulation layer 190. The chambers 220 include but are not limited to chambers configured for IJP, CVD, ALD, sputtering or combinations thereof. The encapsulation layer 190 can be a multi-layer stack. In one embodiment, which can be combined with other embodiments described herein, one encapsulation layer 190 of the one or more encapsulation layers 190 is deposited in one of the chambers 220 utilizing an IJP process. A subsequent encapsulation layer 190 of the one or more encapsulation layers 190 is deposited in one of the chambers 220 utilizing a CVD process.

FIG. 2C is a schematic view of a processing system 200C as described herein. The process system 200C is a multi-chamber system that can form the EL device 100. The processing system 200C is utilized in the method 700, as described herein. The process system 200C includes one or more chambers 221. The one or more chambers 221 are configured to deposit an organic layer 150 and the top electrode layer 170. The organic layer 150 can further include a hole injection layer (HIL) 156, a hole transport layer (HTL) 158, an emissive layer (EML) 160, an electron transport layer (ETL) 162, and an electron injection layer (EIL) 164. The hole injection layer (HIL) 156, the hole transport layer (HTL) 158, the emissive layer (EML) 160, the electron transport layer (ETL) 162, the electron injection layer (EIL) 164, and the top electrode layer 170 can be deposited in the one or more chambers 221. The one or more chambers 221 include but are not limited to chambers configured for thermal evaporation under vacuum, ink jet printing, sputtering, or any other suitable technique, or combinations thereof.

The process system 200C further includes a chamber 222. The chamber 222 is configured to deposit a protection layer 175. The chamber 222 includes, but is not limited to, a chamber configured for CVD, PVD, ALD, sputtering, PECVD, or any other suitable technique, or combinations thereof. In one embodiment, which can be combined with other embodiments described herein, the protection layer 175 is deposited in the chamber 222 utilizing a CVD process. The process system 200C further includes a chamber 223. The chamber 223 is configured to deposit a photoresist 802. The chamber 225 includes, but is not limited to, a chamber configured for slit coating, spin coating, blade coating, spray coating, ink jet printing, or combinations thereof.

The process system 200C further includes a chamber 224. The chamber 224 is configured to expose the photoresist 802 to electromagnetic radiation. The chamber 224 includes, but is not limited to, a chamber configured to have a stepper, scanner or combinations thereof. In one embodiment, which can be combined with other embodiments described herein, a pre-exposure bake is performed on the photoresist 802 prior to entering the chamber 224. In another embodiment, which can be combined with other embodiments described herein, a post-exposure bake is performed on the photoresist 802 after entering the chamber 224.

The process system 200C further includes a chamber 225. The chamber 225 is configured to develop the photoresist 802. The chamber 225 includes, but is not limited to, a chamber configured to have a bath, dipping bath, ultrasonic bath, spray chamber or combinations thereof.

The process system 200C further includes a chamber 226. The chamber 226 is configured to deposit a filler 180. The chamber 228 includes, but is not limited to, a chamber configured for PVD, CVD, PECVD, FCVD, ALD, sputtering, thermal evaporation, ink jet printing (IJP), dip coating, spray coating, blade coating, vapor jet printing, and spin-on coating or any other suitable technique, or combinations thereof. In one embodiment, which can be combined with other embodiments described herein, the filler 180 is disposed in the chamber 226 utilizing an IJP process. The processing system 200C further includes a chamber 227. The chamber 227 is configured to perform a lift-off procedure. The chamber 227 includes, but is not limited to, a chamber configured to have a bath, dipping bath, ultrasonic bath, spray chamber or combinations thereof. The processing system 200C further includes one or more chambers 228. The one or more chambers 228 are configured to dry and/or cure the filler 180. The one or more chambers 228 include but are not limited to chambers configured for vacuum drying, UV exposure, thermal drying, thermal curing, or combinations thereof. The processing system 200C further includes one or more chambers 229. The chambers 229 are configured to deposit an encapsulation layer 190. The chambers 229 include but are not limited to chambers configured for IJP, CVD, ALD, sputtering, or combinations thereof. The encapsulation layer 190 can be a multi-layer stack. In one embodiment, which can be combined with other embodiments described herein, one encapsulation layer 190 of the one or more encapsulation layers 190 is deposited in one of the chambers 229 utilizing an IJP process. A subsequent encapsulation layer 190 of the one or more encapsulation layers 190 is deposited in one of the chambers 229 utilizing a CVD process

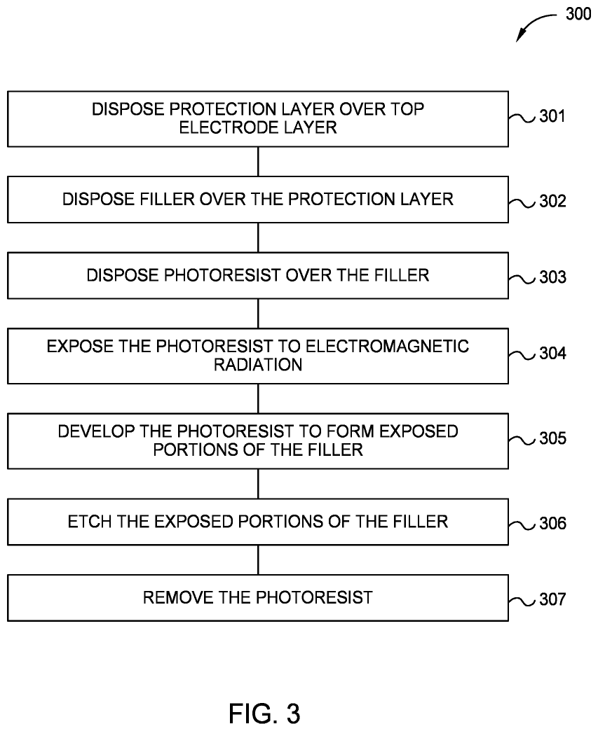

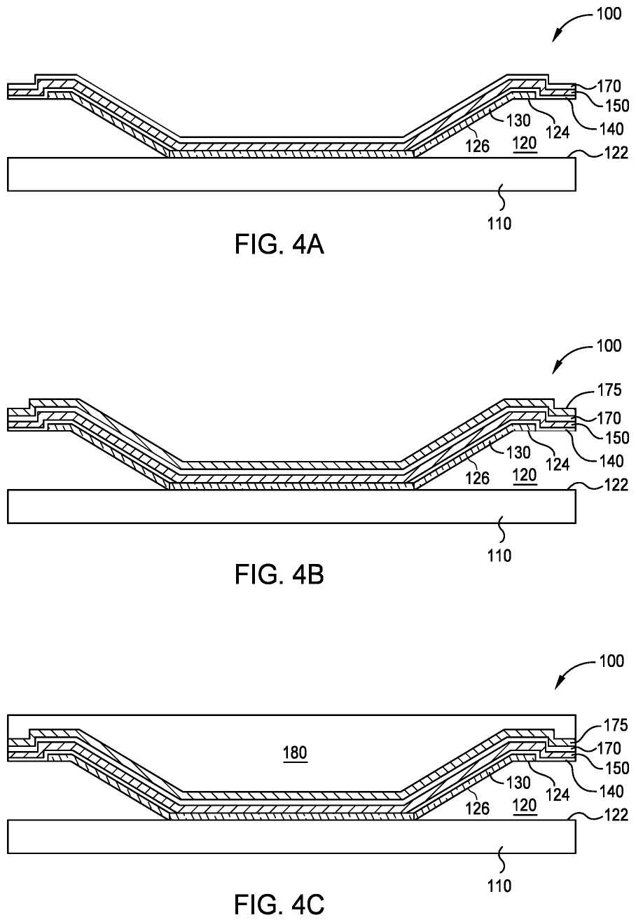

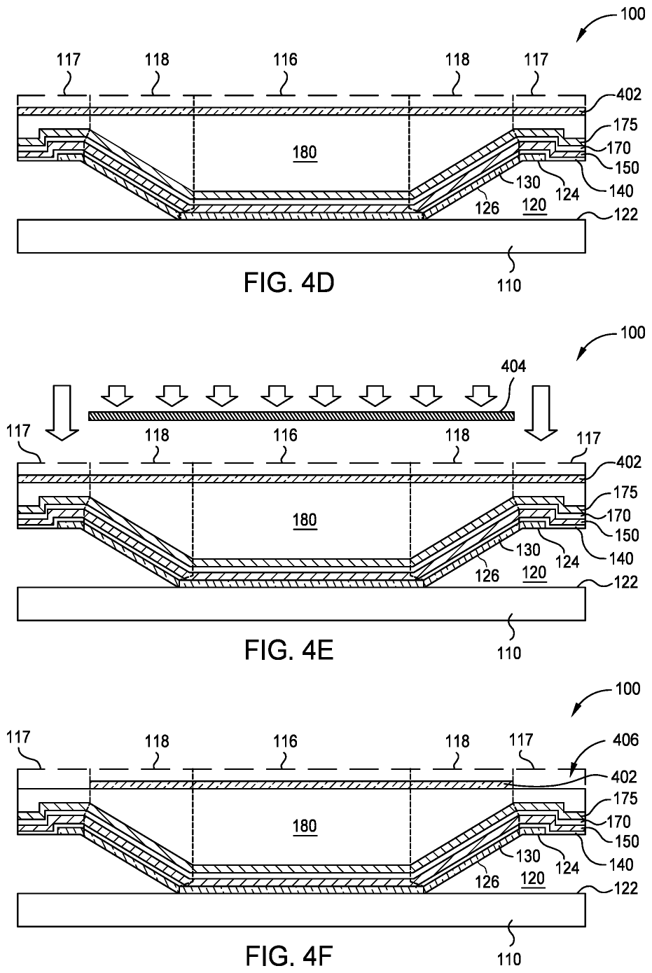

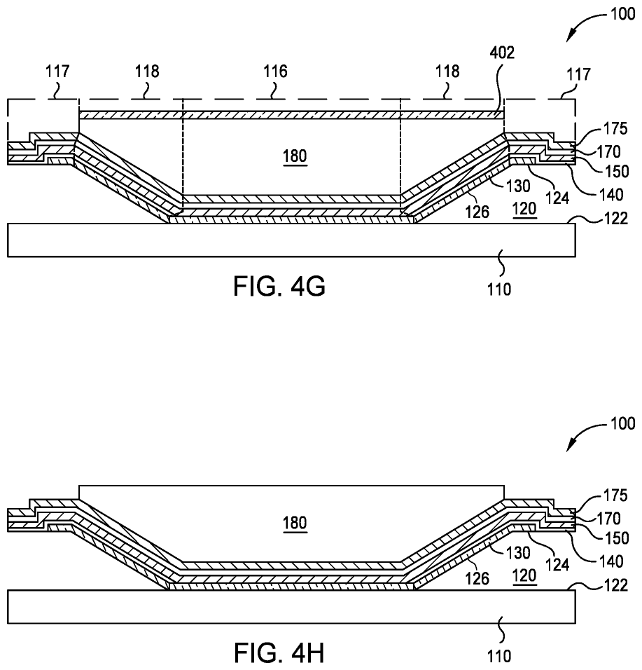

FIG. 3 is a flow diagram of a method 300 for forming an EL device 100. FIGS. 4A-4H are cross-sectional views of a substrate 110 during the method 300 of forming the EL device 100, according to embodiments described herein. To facilitate explanation, the method 300 will be described with reference to the processing system 200A of FIG. 2A. However, it is to be noted that processing systems other than the processing system 200A may be utilized in conjunction with method 300. Although FIGS. 4A-4H depict the EL device 100 as being disposed on the substrate 110, the method 300 may be performed utilizing embodiments including an interconnection layer 114 and a TFT 112, as shown in FIG. 1C.

At operation 301, as shown in FIG. 4B, a protection layer 175 is disposed. The protection layer 175 is disposed over an organic layer 150 and a top electrode layer 170. In one embodiment, which can be combined with other embodiments described herein, the protection layer 175 is conformal to the organic layer 150 and the top electrode layer 170. The protection layer 175 can be disposed on to the EL device 100 in a chamber 202 of the processing system 200A. The chamber 202 can be any chamber suitable to deposit the protection layer 175 such as a chamber configured for CVD, PVD, ALD, sputtering, PECVD, or any other suitable technique, or combinations thereof. The protection layer 175 provides protection of the underlying materials from subsequent processes. In one embodiment, which can be combined with other embodiments described herein, the protection layer 175 is disposed over the organic layer 150 and the top electrode layer 170 in the chamber 202 utilizing a CVD process.

As shown in FIG. 4A, the organic layer 150 and top electrode layer 170 are disposed over the bottom reflective electrode layer 130 and the PDL 120. In one embodiment, which can be combined with other embodiments described herein, the organic layer 150 can further include a hole injection layer (HIL) 156, a hole transport layer (HTL) 158, an emissive layer (EML) 160, an electron transport layer (ETL) 162, and an electron injection layer (EIL) 164. The hole injection layer (HIL) 156, the hole transport layer (HTL) 158, the emissive layer (EML) 160, the electron transport layer (ETL) 162, the electron injection layer (EIL) 164, and the top electrode layer 170 can be sequentially disposed onto the EL device 100 in one or more chambers 201 of the processing system 200A. The chambers 201 can be any chamber suitable to deposit the organic layer 150 and top electrode layer 170 such as chambers configured for thermal evaporation under vacuum, ink jet printing, sputtering, or any other suitable technique, or combinations thereof. The bottom reflective electrode layer 130 is disposed over a pixel defining layer (PDL) 120 and the substrate 110. A dielectric layer 140 is disposed over the bottom reflective layer 130 on the PDL 120 to provide isolation between the bottom reflective electrode layer 130 and the organic layer 150. The PDL 120 is disposed over the substrate 110. In one embodiment, which can be combined with embodiments described herein, the substrate 110 can include features such as a thin-film transistor (TFT) 112 (see FIG. 1C).

At operation 302, as shown in FIG. 4C, a filler 180 is disposed. The filler 180 is disposed over the protection layer 175. The filler 180 can be disposed on to the EL device 100 in a chamber 203 of the processing system 200A. The chamber 203 can be any chamber suitable to deposit the filler 180 such as a chamber configured for PVD, CVD, PECVD, FCVD, ALD, sputtering, thermal evaporation, ink jet printing (IJP), dip coating, spray coating, blade coating, vapor jet printing, and spin-on coating or any other suitable technique, or combinations thereof. In one embodiment, which can be combined with other embodiments described herein, the filler 180 is disposed over the protection layer 175 in the chamber 203 utilizing an IJP process. The IJP process deposits the filler 180 such that the filler is a blanket layer over the protection layer 175. In another embodiment, which can be combined with other embodiments described herein, the filler 180 is cured or dried after the operation 302. In yet another embodiment, which can be combined with other embodiments described herein, the filler 180 is a photosensitive material. In embodiments where the filler 180 is a photosensitive material, operations 303 and 305 of the method 300 are not required because the filler 180 acts as the photosensitive material. Therefore, the filler 180 including the photosensitive material is able to be exposed to electromagnetic radiation and developed to pattern the filler 180 without using a separate photoresist. In this embodiment, the filler 180 including the photosensitive material has a filler refractive index of about 1.8 or greater. Additionally, the filler 180 including the photosensitive material can be a positive photosensitive material or a negative photosensitive material.

At operation 303, as shown in FIG. 4D, a photoresist 402 is disposed. The photoresist 402 is disposed over the filler 180. The photoresist 402 can be disposed on to the EL device 100 in a chamber 204 of the processing system 200A. The chamber 204 can be any chamber suitable to deposit a resist material such as a chamber configured for slit coating, spin coating, blade coating, spray coating, ink jet printing or combinations thereof. The photoresist can be formed from a material that includes, but is not limited to resins, polymers, photosensitive additives, or combinations thereof. The photoresist 402 is a positive photoresist or a negative photoresist. A positive photoresist includes portions of the photoresist, which, when exposed to electromagnetic radiation, are respectively soluble to a resist developer applied to the photoresist after the pattern is written into the photoresist using the electromagnetic radiation. A negative photoresist includes portions of the photoresist, which, when exposed to radiation, will be respectively insoluble to the resist developer applied to the photoresist after the pattern is written into the resist using the electromagnetic radiation. The chemical composition of the resist determines whether the resist is a positive resist or a negative photoresist. Although the embodiment shown in FIGS. 4D-4F utilizes a positive photoresist, a negative photoresist can be utilized as well.

At operation 304, as shown in FIG. 4E, the photoresist 402 is exposed. A proximity mask 404 is positioned above EL device 100 to shield the photoresist 402. The proximity mask 404 shields the photoresist 402 such that there is an unshielded portion of the photoresist 402 that is exposed to electromagnetic radiation. The photoresist 402 can be exposed in a chamber 205 of the processing system 200A. The chamber 205 can be any chamber suitable to expose the photoresist to electromagnetic radiation such as a chamber configured to have a stepper, scanner, or combinations thereof.

In embodiments where the photoresist 402 is a positive photoresist, which can be combined with embodiments described herein, the photoresist 402 corresponding to a planar region 116 and sidewall regions 118 of the EL device 100 is shielded by the proximity mask 404 from the electromagnetic radiation. The photoresist 402 corresponding to PDL regions 117 of the EL device 100 are exposed to electromagnetic radiation. In embodiments where the photoresist 402 is a negative photoresist, which can be combined with embodiments described herein, the photoresist 402 corresponding to the PDL regions 117 of the EL device 100 is shielded by the proximity mask 404 from the electromagnetic radiation. The photoresist 402 corresponding to the planar region 116 and sidewall regions 118 is exposed to electromagnetic radiation.

At operation 305, as shown in FIG. 4F, the photoresist 402 is developed. The proximity mask 404 is removed and a developer is applied to the photoresist 402. The photoresist 402 is either soluble or insoluble to the developer after being exposed to the electromagnetic radiation. Exposed portions 406 of the filler 180 are formed when the portions of the photoresist 402 corresponding to the PDL regions 117 of the EL device 100 are removed. The photoresist 402 can be developed in a chamber 206 of the processing system 200A. The chamber 206 can be any chamber suitable to develop the photoresist 402 such as a chamber configured to have a bath, dipping bath, ultrasonic bath, spray chamber or combinations thereof. In embodiments where the photoresist 402 is a positive photoresist, which can be combined with embodiments described herein, the portions of the photoresist 402 corresponding to the PDL regions 117 of EL device 100 are soluble to the developer. In embodiments where the photoresist 402 is a negative photoresist, which can be combined with embodiments described herein, the portion of the photoresist 402 corresponding to the planar region 116 and sidewall regions 118 of the EL device 100 are insoluble to the developer. The exposed portions 406 of the filler 180 are formed when the photoresist 402 corresponding to the PDL regions 117 of the EL device 100 is dissolved.

At operation 306, as shown in FIG. 4G, the filler 180 is etched. The exposed portions 406 of the filler 180 corresponding to the PDL regions 117 of the EL device 100 are etched. The photoresist 402 functions as an etch stop such that only the exposed portions 406 of the filler are etched and the filler 180 disposed under the photoresist 402 is not etched. Therefore, only the filler 180 corresponding to the planar region 116 and sidewall regions 118 of the EL device 100 remain on the EL device 100. The filler 180 can be etched in a chamber 207 of the processing system 200. The chamber 207 can be any chamber suitable to etch the filler 180 such as a chamber configured for ion-beam etching, reactive ion etching, electron beam etching, wet etching, dry etching, or combinations thereof.

At operation 307, as shown in FIG. 4H, the photoresist 402 is removed. The photoresist 402 can be removed in a chamber 208 of the processing system 200A. The chamber 208 can be any chamber suitable to remove the photoresist 402 such as a chamber configured to have a bath, dipping bath, ultrasonic bath, spray chamber or combinations thereof. In one embodiment, which can be combined with other embodiments described herein, the filler 180 is cured after the photoresist 402 is removed. In another embodiment, which can be combined with other embodiments described herein, the filler 180 is cured before the photoresist 402 is removed i.e., prior to operation 307. In yet another embodiment, which can be combined with other embodiments described herein, the filler 180 is dried after the photoresist 402 is removed. In yet another embodiment, which can be combined with other embodiments described herein, the filler 180 can be dried before the photoresist 402 is removed i.e., prior to operation 307. The filler 180 is dried to evaporate any remaining process solvents or liquids. The filler 180 can be dried and/or cured in one or more chambers 209 of the processing system 200A. The chambers 209 can be any chamber suitable to dry and/or cure the filler 180 such as chambers configured for vacuum drying, UV exposure thermal drying, thermal curing, or combinations thereof.

In one embodiment, which can be combined with other embodiments described herein, an encapsulation layer 190 can be disposed over the filler 180 and the protection layer 175. The encapsulation layer 190 protects the EL device 100 from moisture and oxygen ingress. In one embodiment, which can be combined with other embodiments described herein, the encapsulation layer 190 can be one or more encapsulation layers 190. The one or more encapsulation layers 190 can be disposed in one or more chambers 210 of the processing system 200A. The chambers 210 can be any chamber suitable to deposit the encapsulation layer 190 such as chambers configured for IJP, CVD, ALD, sputtering, or combinations thereof. In one embodiment, which can be combined with other embodiments described herein, one encapsulation layer 190 of the one or more encapsulation layers 190 is deposited in one of the chambers 210 utilizing an IJP process. A subsequent encapsulation layer 190 of the one or more encapsulation layers 190 is deposited in one of the chambers 210 utilizing a CVD process.

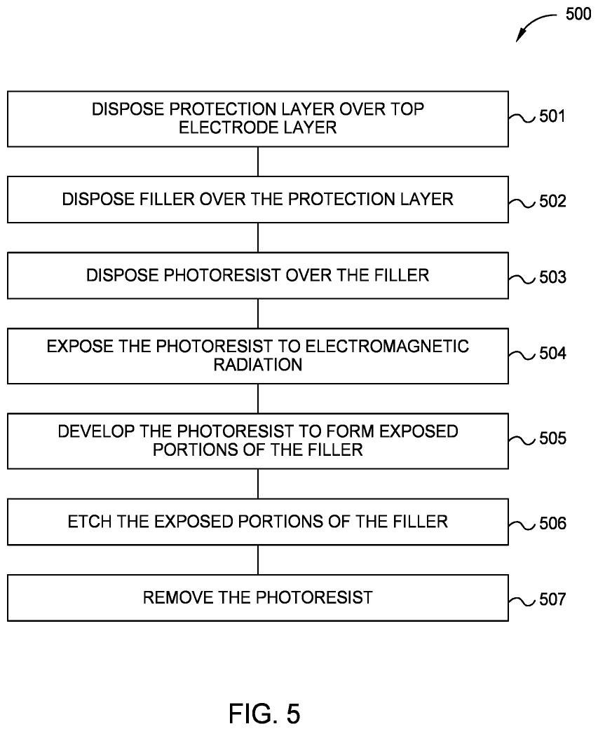

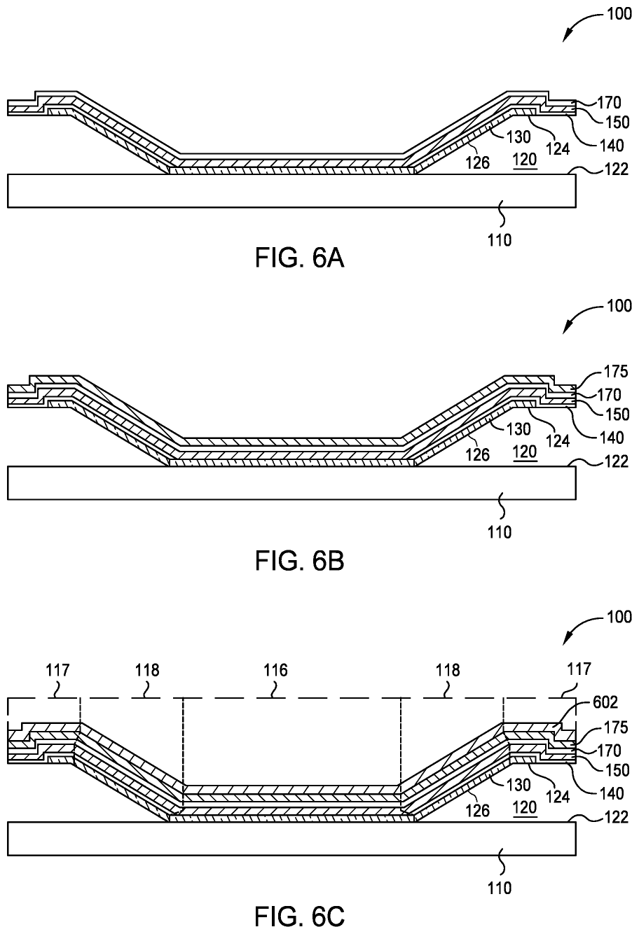

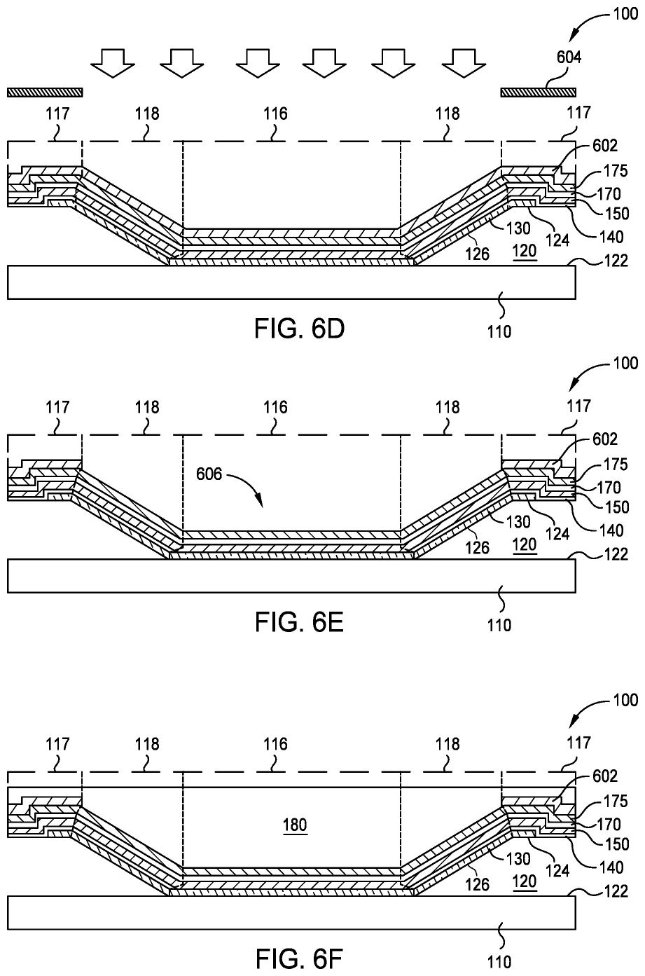

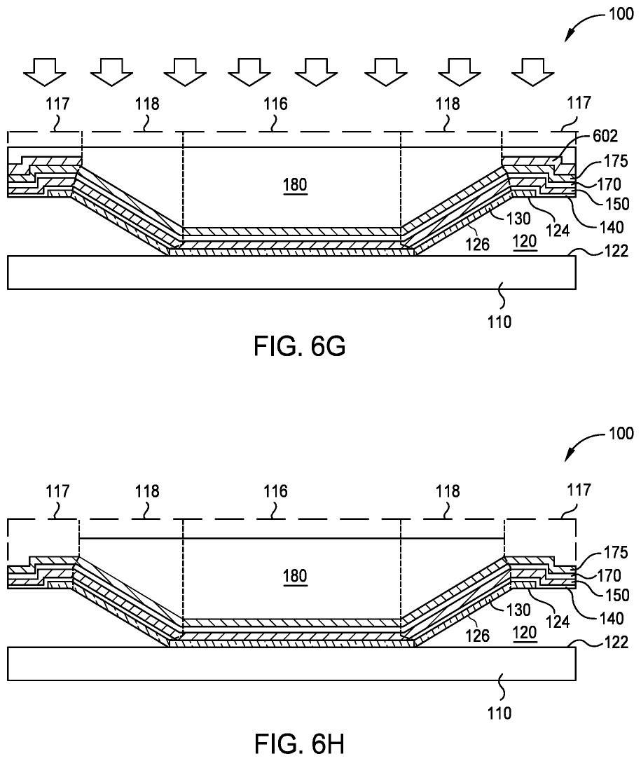

FIG. 5 is a flow diagram of a method 500 for forming an EL device 100. FIGS. 6A-6H are cross-sectional views of a substrate 110 during the method 500 of forming the EL device 100. To facilitate explanation, the method 500 will be described with reference to the processing system 200B of FIG. 2B. However, it is to be noted that processing systems other than the processing system 200B may be utilized in conjunction with method 500. Although FIGS. 6A-6H depict the EL device 100 as being disposed on the substrate 100, the method 500 may be performed utilizing embodiments including an interconnection layer 114 and a TFT 112, as shown in FIG. 1C.

At operation 501, as shown in FIG. 6B, a protection layer 175 is disposed. The protection layer 175 is disposed over the organic layer 150 and the top electrode layer 170. In one embodiment, which can be combined with other embodiments described herein, the protection layer 175 is conformal to the organic layer 150 and the top electrode layer 170. The protection layer 175 can be disposed on to the EL device 100 in a chamber 212 of the processing system 200B. The chamber 212 can be any chamber suitable to deposit the protection layer 175 such as a chamber configured for CVD, PVD, ALD, sputtering, PECVD, or any other suitable technique, or combinations thereof. The protection layer 175 provides protection of the underlying materials from subsequent processes. In one embodiment, which can be combined with other embodiments described herein, the protection layer 175 is disposed over the organic layer 150 and the top electrode layer 170 in the chamber 212 utilizing a CVD process.

As shown in FIG. 6A, the organic layer 150 and the top electrode layer 170 are disposed over the bottom reflective electrode layer 130 and the PDL 120. In one embodiment, which can be combined with other embodiments described herein, the EL device 100 can further include a hole injection layer (HIL) 156, a hole transport layer (HTL) 158, an emissive layer (EML) 160, an electron transport layer (ETL) 162, and an electron injection layer (EIL) 164. The hole injection layer (HIL) 156, the hole transport layer (HTL) 158, the emissive layer (EML) 160, the electron transport layer (ETL) 162, the electron injection layer (EIL) 164, and the top electrode layer 170 can be sequentially disposed onto the EL device 100 in one or more chambers 211 of the processing system 200B. The chambers 211 can be any chamber suitable to deposit the organic layer 150 such as chambers configured for thermal evaporation under vacuum, ink jet printing, sputtering, or any other suitable technique, or combinations thereof. The bottom reflective electrode layer 130 is disposed over a PDL 120. A dielectric layer 140 is disposed over the bottom reflective electrode layer 130 on the PDL 120 to provide isolation between the bottom reflective electrode layer 130 and the organic layer 150. The PDL 120 is disposed over the substrate 110. In one embodiment, which can be combined with embodiments described herein, the substrate 110 can include features such as a thin-film transistor (TFT) 112 (see FIG. 1C).

At operation 502, as shown in FIG. 6C, a photoresist 602 is disposed. The photoresist 602 is disposed over the protection layer 175. In one embodiment, which can be combined with other embodiments described herein, the photoresist 602 is conformal with the protection layer 175. The photoresist 602 can be disposed on to the protection layer 175 in a chamber 213 of the processing system 200B. The chamber 213 can be any chamber suitable to deposit a resist material such as a chamber configured for slit coating, spin coating, blade coating, spray coating, ink jet printing or combinations thereof. The photoresist can be formed from a material that includes, but is not limited to resins, polymers, photosensitive additives, or combinations thereof. The photoresist 602 is a positive photoresist or a negative photoresist. Although the embodiment shown in FIGS. 6C-6G utilizes a positive photoresist, a negative photoresist can be utilized as well.

At operation 503, as shown in FIG. 6D, the photoresist 602 is exposed. A proximity mask is 604 is positioned above the EL device 100 to shield the photoresist 602. The proximity mask 404 shields the photoresist 602 such that there is an unshielded portion of the photoresist 602 that is exposed to electromagnetic radiation. The photoresist 602 can be exposed in a chamber 214 of the processing system 200B. The chamber 214 can be any chamber suitable to expose the photoresist to electromagnetic radiation such as a chamber configured to have a stepper, scanner, or combinations thereof.

In embodiments where the photoresist 602 is a positive photoresist, which can be combined with embodiments described herein, the photoresist 602 corresponding to PDL regions 117 of the EL device 100 is shielded by the proximity mask 604 from the electromagnetic radiation. The photoresist 602 corresponding to a planar region 116 and sidewall regions 118 the EL device 100 is exposed to electromagnetic radiation. In embodiments where the photoresist 602 is a negative photoresist, the photoresist 602 corresponding to the planar region 116 and the sidewall regions 118 of the EL device 100 is shielded from the electromagnetic radiation. The photoresist 602 corresponding to the PDL regions 117 of the EL device 100 is exposed to electromagnetic radiation.

At operation 504, as shown in FIG. 6E, the photoresist 602 is developed. The proximity mask 604 is removed and the developer is applied to the photoresist 602. The photoresist 602 is either soluble or insoluble to a developer after being exposed to the electromagnetic radiation. An exposed portion 606 of the protection layer 175 is formed when the portion of the photoresist 602 corresponding to the planar region 116 and the sidewall regions 118 of the EL device 100 are removed. The photoresist 602 can be developed in a chamber 215 of the processing system 200B. The chamber 215 can be any chamber suitable to develop the photoresist 602 such as a chamber configured to have a bath, dipping bath, ultrasonic bath, spray chamber, or combinations thereof. In embodiments where the photoresist 602 is a positive photoresist, which can be combined with embodiments described herein, the photoresist 402 corresponding to the planar region 116 and the sidewall regions 118 of the EL device 100 is soluble to the developer. In embodiments where the photoresist 602 is a negative photoresist, which can be combined with embodiments described herein, the photoresist 602 corresponding to the PDL regions 117 of the EL device 100 is insoluble to the developer.

At operation 505, as shown in FIG. 6F, a filler 180 is disposed. The filler 180 is disposed over the protection layer 175 and over the photoresist 602. The filler 180 can be disposed on to the EL device 100 in a chamber 216 of the processing system 200B. The chamber 216 can be any chamber suitable to deposit the filler 180 such as a chamber configured for PVD, CVD, PECVD, FCVD, ALD, sputtering, thermal evaporation, ink jet printing (IJP), dip coating, spray coating, blade coating, vapor jet printing, and spin-on coating or any other suitable technique, or combinations thereof. In one embodiment, which can be combined with other embodiments described herein, the filler 180 is disposed over the protection layer 175 and the photoresist 602 in the chamber 216 utilizing an IJP process. The IJP process deposits the filler 180 such that the filler is a blanket layer over the protection layer 175 and the photoresist 402. In another embodiment, which can be combined with other embodiments described herein, the filler 180 is cured or dried after the operation 505. In another embodiment, which can be combined with other embodiments described herein, the filler 180 is a photosensitive material. In embodiments where the filler 180 is a photosensitive material, operations 502, 503, and 504 of the method 500 are not required because the filler 180 acts as the photosensitive material. Therefore, the filler 180 including the photosensitive material is able to be exposed to electromagnetic radiation and developed to pattern the filler 180 without using a separate photoresist. Additionally, the filler 180 including the photosensitive material can be a positive photosensitive material or a negative photosensitive material.

At operation 506, as shown in FIG. 6G, the filler 180 is cured and the photoresist 402 is exposed. The filler 180 and photoresist can be cured and exposed in a chamber 217 of the processing system 200B. The chamber 217 can be any chamber suitable to expose the filler 180 to the curing agent such as a chamber configured for UV radiation, thermal curing, or combinations thereof.

At operation 507, as shown in FIG. 6H, the photoresist 602 is removed. The photoresist was depolymerized in operation 506 and is able to be removed. The photoresist 402 can be removed in a chamber 220 of the processing system 200B. The chamber 218 can be any chamber suitable to remove the photoresist 602 such as a chamber configured to have a bath, dipping bath, ultrasonic bath, spray chamber and combinations thereof. In one embodiment, which can be combined with other embodiments described herein, the filler 180 corresponding to the planar region 116 and the sidewall regions 118 of the EL device 100 is dried. In another embodiment, which can be combined with other embodiments described herein, the filler 180 can be dried before the filler 180 is removed i.e., prior to operation 507. The filler 180 is dried to evaporate any remaining process solvents and/or liquids. The filler 180 can be dried in a chamber 219 of the processing system 200B. The chamber 219 can be any chamber suitable to dry the filler 180 such as chambers configured for vacuum drying, thermal drying, or combinations thereof.

In one embodiment, which can be combined with other embodiments described herein, an encapsulation layer 190 can be disposed over the filler 180 and the protection layer 175. The encapsulation layer 190 protects the EL device 100 from moisture and oxygen ingress. In one embodiment, which can be combined with other embodiments described herein, the encapsulation layer 190 can be one or more encapsulation layers 190. The one or more encapsulation layers 190 can be disposed in one or more chambers 220 of the processing system 200B. The chambers 220 can be any chamber suitable to deposit the encapsulation layer 190 such as chambers configured for IJP, CVD, ALD, sputtering, or combinations thereof. In one embodiment, which can be combined with other embodiments described herein, one encapsulation layer 190 of the one or more encapsulation layers 190 is deposited in one of the chambers 220 utilizing an IJP process. A subsequent encapsulation layer 190 of the one or more encapsulation layers 190 is deposited in one of the chambers 220 utilizing a CVD process.

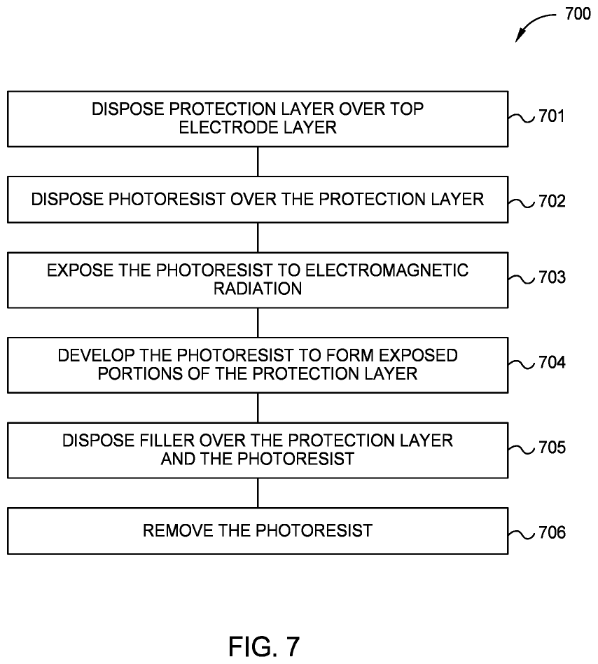

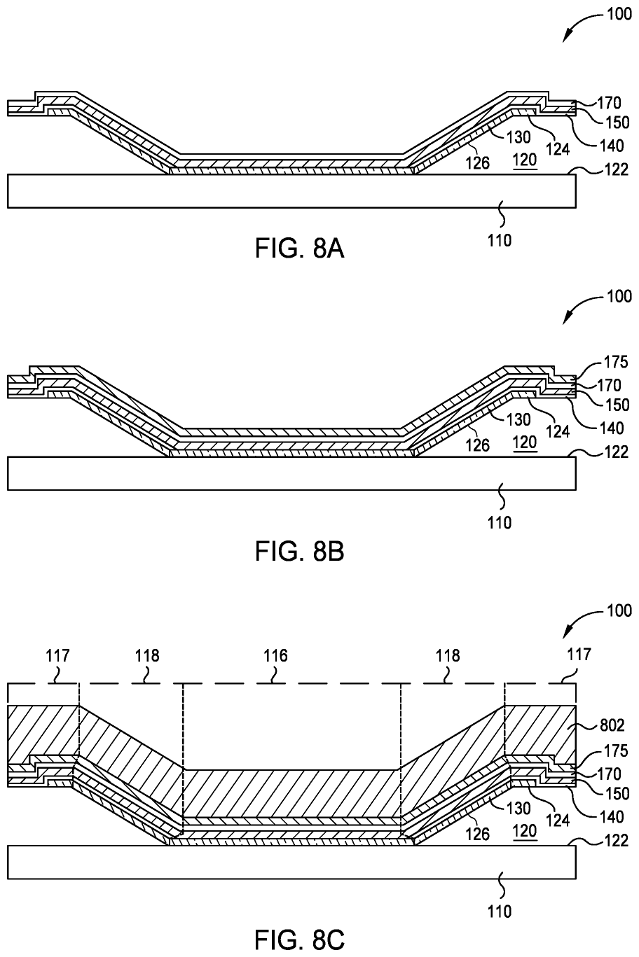

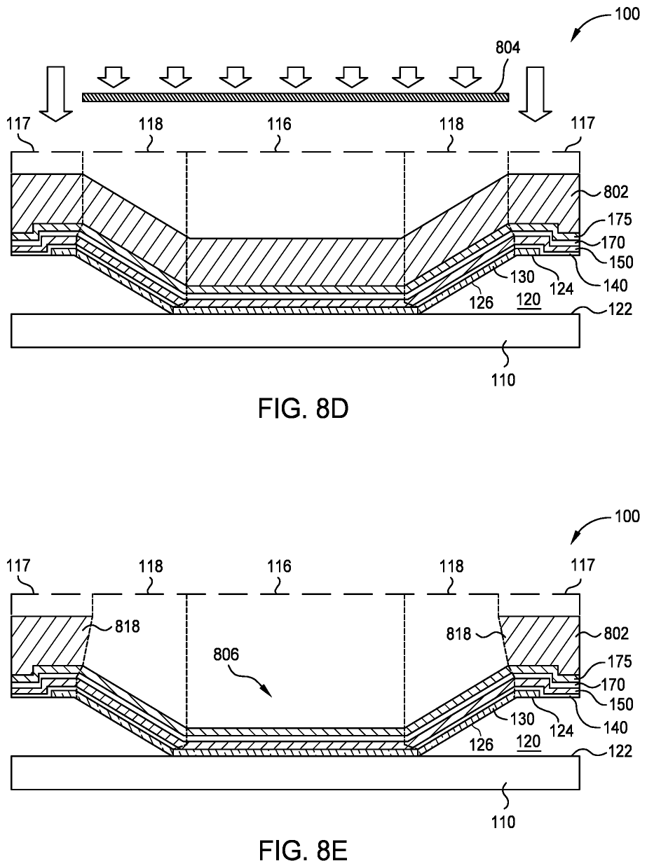

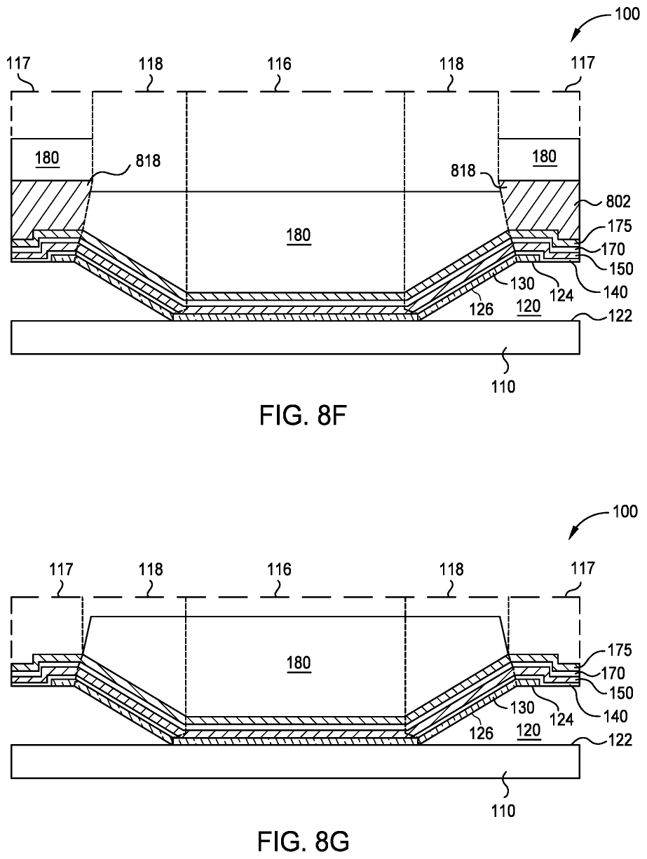

FIG. 7 is a flow diagram of a method 700 for forming an EL device 100. FIGS. 8A-8G are cross-sectional views of a substrate 110 during the method 700 of forming the EL device 100. To facilitate explanation, the method 700 will be described with reference to the processing system 200C of FIG. 2C. However, it is to be noted that processing systems other than the processing system 200C may be utilized in conjunction with method 700. Although FIGS. 8A-8G depict the EL device 100 as being disposed on the substrate 100, the method 700 may be performed utilizing embodiments including an interconnection layer 114 and a TFT 112, as shown in FIG. 1C.

At operation 701, as shown in FIG. 8B, a protection layer 175 is disposed. The protection layer 175 is disposed over the organic layer 150 and the top electrode layer 170. In one embodiment, which can be combined with other embodiments described herein, the protection layer 175 is conformal to the organic layer 150 and the top electrode layer 170. The protection layer 175 can be disposed on to the EL device 100 in a chamber 222 of the processing system 200C. The chamber 222 can be any chamber suitable to deposit the protection layer 175 such as a chamber configured for CVD, PVD, ALD, sputtering, PECVD, or any other suitable technique, or combinations thereof. The protection layer 175 provides protection of the underlying materials from subsequent processes. In one embodiment, which can be combined with other embodiments described herein, the protection layer 175 is disposed over the organic layer 150 and the top electrode layer 170 in the chamber 222 utilizing a CVD process.

As shown in FIG. 8A, the organic layer 150 is disposed over the bottom reflective electrode layer 130 and the PDL 120. In one embodiment, which can be combined with other embodiments described herein, the organic layer 150 can further include a hole injection layer (HIL) 156, a hole transport layer (HTL) 158, an emissive layer (EML) 160, an electron transport layer (ETL) 162, and an electron injection layer (EIL) 164. The hole injection layer (HIL) 156, the hole transport layer (HTL) 158, the emissive layer (EML) 160, the electron transport layer (ETL) 162, the electron injection layer (EIL) 164, and the top electrode layer 170 can be sequentially disposed onto the EL device 100 in one or more chambers 221 of the processing system 200C. The chambers 221 can be any chamber suitable to deposit the organic layer 150 such as chambers 221 configured for thermal evaporation under vacuum, ink jet printing, sputtering, or any other suitable technique, or combinations thereof. The bottom reflective electrode layer 130 is disposed over the PDL 120. A dielectric layer 140 is disposed over the bottom reflective layer 130 on the PDL 120 to provide isolation between the bottom reflective electrode layer 130 and the organic layer 150. The PDL 120 is disposed over the substrate 110. In one embodiment, which can be combined with embodiments described herein, the substrate 110 can include features such as a thin-film transistor (TFT) 112 (see FIG. 1C).

At operation 702, as shown in FIG. 8C, a photoresist 802 is disposed. The photoresist 802 is disposed over the protection layer 175. In one embodiment, which can be combined with other embodiments described herein, the photoresist 802 is conformal with the protection layer 175. The photoresist 802 can be disposed on to the protection layer 175 in a chamber 223 of the processing system 200C. The chamber 223 can be any chamber suitable to deposit a resist material such as a chamber configured for slit coating, spin coating, blade coating, spray coating, ink jet printing, or combinations thereof. The photoresist can be formed from a material that includes, but is not limited to resins, polymers, photosensitive additives, or combinations thereof. The photoresist 802 is a positive photoresist or a negative photoresist. Although the embodiments shown in FIGS. 8C-8F utilizes a negative photoresist, a positive photoresist can be utilized as well.

At operation 703, as shown in FIG. 8D, the photoresist 802 is exposed. A proximity mask is 804 is positioned above the EL device 100 to shield the photoresist 802. The proximity mask 804 shields the photoresist 802 such that there is a portion of the photoresist 802 that is exposed to electromagnetic radiation. The photoresist 602 can be exposed in a chamber 224 of the processing system 200C. The chamber 224 can be any chamber suitable to expose the photoresist to electromagnetic radiation such as a chamber configured to have a stepper, scanner, or combinations thereof.

In embodiments where the photoresist 802 is a positive photoresist, which can be combined with embodiments described herein, the photoresist 802 corresponding to PDL regions 117 of the EL device 100 is shielded by the proximity mask 804 from the electromagnetic radiation. The photoresist 802 corresponding to a planar region 116 and sidewall regions 118 of the EL device 100 is exposed to electromagnetic radiation. In embodiments where the photoresist 802 is a negative photoresist, which can be combined with embodiments described herein, the photoresist 802 corresponding to the planar region 116 and sidewall regions 118 of the EL device 100 is shielded by the proximity mask 804 from the electromagnetic radiation. The photoresist 802 corresponding to the PDL regions 117 of the EL device 100 is exposed to electromagnetic radiation.

At operation 704, as shown in FIG. 8E, the photoresist 802 is developed. The proximity mask 804 is removed and the developer is applied to the photoresist 802. The photoresist 802 is either soluble or insoluble to a developer after being exposed to the electromagnetic radiation. An exposed portion 806 of the protection layer 175 is formed when the portions of the photoresist 802 corresponding to the planar region 116 and the sidewall regions 118 of the EL device 100 are removed. The photoresist 802 can be developed in a chamber 225 of the processing system 200C. The chamber 225 can be any chamber suitable to develop the photoresist 802 such as a chamber configured to have a bath, dipping bath, ultrasonic bath, spray chamber, or combinations thereof. In embodiments where the photoresist 802 is a positive photoresist, which can be combined with embodiments described herein, the photoresist 802 corresponding to the planar region 116 and the sidewall regions 118 of the EL device 100 is soluble to the developer. In embodiments where the photoresist 802 is a negative photoresist, which can be combined with embodiments described herein, the photoresist 802 corresponding to the PDL regions 117 of the EL device 100 is insoluble to the developer.

At operation 705, as shown in FIG. 8F, a filler 180 is disposed. The filler 180 is disposed over the protection layer 175 and over the photoresist 802. In one embodiment, which can be combined with other embodiments described herein, the filler 180 is disposed on the protection layer 175 and on the photoresist 802 corresponding to the PDL regions 117 of the EL device 100. The filler 180 corresponding to the planar region 116 and the sidewall regions 118 of the EL device 100 is disposed over the protection layer 175. The filler 180 corresponding to the planar region 116 and the sidewall regions 118 is not planar with the photoresist 802 i.e., the filler 180 corresponding to the planar region 116 and the sidewall regions 118 is disposed below the photoresist 802. Therefore, the filler 180 exposes sidewalls 818 of the photoresist. The filler 180 can be disposed on to the EL device 100 in a chamber 226 of the processing system 200C. The chamber 226 can be any chamber suitable to deposit the filler 180 such as a chamber configured for PVD, CVD, PECVD, FCVD, ALD, sputtering, thermal evaporation, ink jet printing (IJP), dip coating, spray coating, blade coating, vapor jet printing, and spin-on coating or any other suitable technique, or combinations thereof. In one embodiment, which can be combined with other embodiments described herein, the filler 180 is disposed over the protection layer 175 and the photoresist 802 in the chamber 226 utilizing an IJP process. The IJP process deposits the filler 180 such that the filler is a blanket layer over the protection layer 175 and the photoresist 402. In another embodiment, which can be combined with other embodiments described herein, the filler 180 is cured or dried after the operation 705.

At operation 706, as shown in FIG. 8G, the photoresist 802 is removed. The photoresist 802 corresponding to the PDL regions 117 of the EL device 100 is removed with a lift off procedure. During the lift off procedure, a lift off procedure chemical contacts the exposed sidewalls 818 of the photoresist 802. The lift off procedure chemical dissolves the photoresist 802 and substantially removes the photoresist 802. The filler 180 corresponding to the PDL regions 117 of the EL device 100 disposed over the photoresist 802 is also substantially removed by being disposed on the photoresist 802. The lift off procedure can be performed in chamber 227. The chamber 227 can be any chamber suitable to perform a lift off procedure such as a chamber configured to have a bath, dipping bath, ultrasonic bath, spray chamber, or combinations thereof.

In one embodiment, which can be combined with other embodiments described herein, the filler 180 is cured. The filler 180 is exposed to a blanket curing process. The blanket curing process cures the filler 180 corresponding to the planar region 116 and the sidewall regions 118 of the EL device 100. In one embodiment, which can be combined with other embodiments described herein, the filler 180 is cured after the photoresist 802 is removed. In another embodiment, which can be combined with other embodiments described herein, the filler 180 is cured before the photoresist 802 is removed i.e., prior to operation 706. In another embodiment, which can be combined with other embodiments described herein, the filler 180 is dried after the photoresist 802 is removed. In yet another embodiment, which can be combined with other embodiments described herein, the filler 180 can be dried before the filler 180 is removed i.e., prior to operation 706. The filler 180 is dried to evaporate any remaining process solvents and/or liquids. The filler 180 can be dried and/or cured in one or more chambers 228 of the processing system 200C. The chambers 228 can be any chamber suitable to cure and dry the filler 180 such as chambers configured for vacuum drying, UV exposure, thermal drying, thermal curing or combinations thereof.

In one embodiment, which can be combined with other embodiments described herein, an encapsulation layer 190 can be disposed over the filler 180 and the protection layer 175. The encapsulation layer 190 protects the EL device 100 from moisture and oxygen ingress. In one embodiment, which can be combined with other embodiments described herein, the encapsulation layer 190 can be one or more encapsulation layers 190. The one or more encapsulation layers 190 can be disposed in one or more chambers 229 of the processing system 200C. The chambers 229 can be any chamber suitable to deposit the encapsulation layer 190 such as chambers configured for IJP, CVD, ALD, sputtering, or combinations thereof. In one embodiment, which can be combined with other embodiments described herein, one encapsulation layer 190 of the one or more encapsulation layers 190 is deposited in one of the chambers 229 utilizing an IJP process. A subsequent encapsulation layer 190 of the one or more encapsulation layers 190 is deposited in one of the chambers 229 utilizing a CVD process.

In summation, embodiments of the present disclosure generally relate to electroluminescent (EL) devices. More specifically, embodiments described herein relate to methods for forming an arrays of the EL devices and selectively patterning a filler material in the EL devices. The filler is patterned in the EL devices using methods described herein. The methods 300, 500, and 700 pattern the filler and provide large area, low cost, and high resolution EL device formation by not relying on ink-jet printing or thermal evaporation with a fine metal mask. The EL device formed from the methods described herein will have improved outcoupling efficiency because of the patterned filler.

While the foregoing is directed to examples of the present disclosure, other and further examples of the disclosure may be devised without departing from the basic scope thereof, and the scope thereof is determined by the claims that follow.

What is claimed is:

1. A method, comprising:
disposing a protection layer over a top electrode layer of an electroluminescent (EL) device;
disposing a filler on the protection layer;
disposing a photoresist on the filler, the photoresist disposed over a planar region, sidewall regions, and pixel defining layer (PDL) regions of the EL device, the planar region and the sidewall regions corresponding to an area of the EL device to have the filler disposed thereover;
patterning the photoresist, the patterning of the photoresist including removing portions of the photoresist corresponding to the PDL regions of the EL device;
etching exposed portions of the filler corresponding to the PDL regions of the EL device, the filler remaining over the planar region and the sidewall regions of the EL device; and
removing the photoresist.

2. The method of claim 1, further comprising curing the filler and drying the filler.

3. The method of claim 1, further comprising disposing at least one encapsulation layers on the filler and on the protection layer.

4. The method of claim 1, wherein the filler includes one or more of organic materials, inorganic materials, polymers, resins, or combinations thereof.

5. The method of claim 1, wherein the EL device further comprises:
a hole injection layer (HIL);
a hole transport layer (HTL);
an emissive layer (EML);
an electron transport layer (ETL); and
an electron injection layer (EIL).

6. The method of claim 1, wherein the protection layer is disposed in a chemical vapor deposition chamber.

7. The method of claim 1, wherein the photoresist is one of a positive photoresist or a negative photoresist.

8. The method of claim 1, wherein the disposing the filler on the protection layer is by an ink-jet printing process.

9. The method of claim 1, wherein at least one portion of a bottom reflective electrode layer is disposed on a PDL and at least one portion of the bottom reflective electrode layer is disposed on one of an interconnection layer or a substrate.

10. A method, comprising:
disposing a protection layer over a top electrode layer of an electroluminescent (EL) device;
disposing a photoresist on the protection layer, the photoresist disposed over a planar region, sidewall regions, and PDL regions of the EL device, the planar region and the sidewall regions corresponding to an area of the EL device to have a filler disposed thereover;
patterning the photoresist, the patterning of the photoresist including removing portions of the photoresist corresponding to the planar region and the sidewall regions of the EL device;
disposing the filler on the photoresist and exposing the filler and remaining photoresist; and
removing the photoresist.

11. The method of claim 10, further comprising drying the filler.

12. The method of claim 10, further comprising disposing at least one encapsulation layers on the filler and on the protection layer.

13. The method of claim 10, wherein the disposing the filler on the photoresist is by an ink-jet printing process.

14. The method of claim 10, wherein the filler includes one or more of organic materials, inorganic materials, polymers, resins, or combinations thereof.

15. A method, comprising:
disposing a protection layer over a top electrode layer of an electroluminescent (EL) device;
disposing a photoresist on the protection layer, the photoresist disposed over a planar region, sidewall regions, and PDL regions of the EL device, the planar region and the sidewall regions corresponding to an area of the EL device to have a filler disposed thereover;
patterning the photoresist, the patterning of the photoresist including removing portions of the photoresist corresponding to the planar region and the sidewall regions of the EL device;
disposing the filler on exposed portions of the protection layer corresponding to the planar region and the sidewall regions of the EL device and on the photoresist; and
removing the photoresist and the filler corresponding to the PDL regions of the EL device.

16. The method of claim 15, further comprising drying the filler.

17. The method of claim 15, further comprising disposing at least one encapsulation layers on the filler and on the protection layer.

18. The method of claim 15, wherein the filler corresponding to the planar region and the sidewall regions is disposed below the photoresist.

19. The method of claim 15, wherein the photoresist is one of a positive photoresist or a negative photoresist.

20. The method of claim 15, wherein the filler includes one or more of organic materials, inorganic materials, polymers, resins, or combinations thereof.
